(19) United States
(12) Patent Application Publication
(10) Pub. No.: US 2025/0364299 A1
(43) Pub. Date: Nov. 27, 2025

(54) CARBON COATED SILICON CARBIDE VACUUM WAFER CHUCK TO CONTROL ELECTROSTATIC DISCHARGE TO WAFER

(71) Applicant: KLA Corporation, Milpitas, CA (US)

(72) Inventor: Ryan Flores, Santa Clara, CA (US)

(21) Appl. No.: 19/090,842

(22) Filed: Mar. 26, 2025

Related U.S. Application Data
(60) Provisional application No. 63/649,949, filed on May 21, 2024.

(51) Int. Cl. H01L 21/683

(52) U.S. Cl. CPC H01L 21/6838

(57) ABSTRACT

A vacuum chuck may include a chuck body formed from silicon carbide. A carbon coating, such as a diamond-like carbon coating, may be deposited on the chuck body. Coating the silicon carbide vacuum chucks with the carbon coatings may control electrostatic discharge events. The carbon coatings may increase the surface resistance of the chuck body and bring the vacuum chucks to within an electrostatic discharge specification which is a tightening specification in the semiconductor industry.

### CROSS-REFERENCE TO RELATED APPLICATIONS

The present application claims the benefit under 35 U.S.C. § 119 (e) of U.S. Provisional Application Ser. No. 63/649,949, filed on May 21, 2024, which is incorporated herein by reference in the entirety.

### TECHNICAL FIELD

The present disclosure generally relates to an apparatus adapted for handling wafers, and, more particularly, to an apparatus for supporting or gripping wafers using a vacuum.

### BACKGROUND

During wafer metrology, inspection, or process, wafers are typically secured with a chuck. The type of chuck used to secure the wafer depends on the nature of the processing. Electrostatic chucks (ESC) and vacuum chucks are commonly used. Vacuum chucks may be either passive or active in nature. Passive vacuum chucks typically have vacuum zones delineated by rings on the surface of the chuck connected by low conductance apertures. Active vacuum chucks typically have independent solenoid valves that control the vacuum applied to each zone. This allows the clamping method across the wafer to be timed.

Electrostatic discharge (ESD) may occur between the chucks and a wafer disposed on the chucks. As the wafer is placed on the chuck by an end effector, there is a voltage potential across the wafer and the chuck. The voltage potential raises a risk of the electrostatic discharge. The electrostatic discharge may damage semiconductor components on the wafers. Electrostatic chucks control for electrostatic discharge by controlling the falling edge of voltage waveforms. The shape of the voltage waveforms may be tailored to minimize possibility of electrostatic discharge events.

Vacuum chucks are also used to hold wafers. For example, vacuum chucks can be used to hold semiconductor wafers during inspection or during other periods of wafer manufacturing. Vacuum chucks typically have a chucking surface that contacts the wafer. One or more vacuum grooves extend through this chucking surface. Suction forces retain a wafer on the vacuum chuck when air or another gas is evacuated through the vacuum groove or grooves. A pressure difference between the chucking surface and opposing wafer surface holds the wafer in place during processing or can flatten the wafer against the vacuum chuck. Controlling the shape of the voltage waveforms to prevent electrostatic discharge is not applicable to vacuum chucks because the vacuum chucks do not use electrostatics to hold the wafer. Therefore, it would be advantageous to provide a device, system, and method that cures the shortcomings described above.

### SUMMARY

A vacuum chuck is described, in accordance with one or more embodiments of the present disclosure. The vacuum chuck may include: a chuck body, wherein the chuck body is formed from silicon carbide, wherein the chuck body includes an unpolished surface, a plurality of sealing rings, a plurality of vacuum holes, and a polished surface, wherein the plurality of sealing rings axially extend from the unpolished surface, wherein the plurality of vacuum holes are defined by the unpolished surface, wherein the polished surface is a top surface of the chuck body, wherein the polished surface is defined by at least the plurality of sealing rings; a bottom cover; an adhesive layer, wherein the adhesive layer adheres together the chuck body and the bottom cover; and a carbon coating, wherein the carbon coating is deposited on the polished surface, wherein the carbon coating has a thickness equal to or less than ten micrometers.

An inspection system is described, in accordance with one or more embodiments of the present disclosure. The inspection system may include: a vacuum chuck. The vacuum chuck may include: a chuck body, wherein the chuck body is formed from silicon carbide, wherein the chuck body includes an unpolished surface, a plurality of sealing rings, a plurality of vacuum holes, and a polished surface, wherein the plurality of sealing rings axially extend from the unpolished surface, wherein the plurality of vacuum holes are defined by the unpolished surface, wherein the polished surface is a top surface of the chuck body, wherein the polished surface is defined by at least the plurality of sealing rings; a bottom cover; an adhesive layer, wherein the adhesive layer adheres together the chuck body and the bottom cover; and a carbon coating, wherein the carbon coating is deposited on the polished surface, wherein the carbon coating has a thickness equal to or less than ten micrometers.

A method of manufacturing a vacuum chuck is described, in accordance with one or more embodiments of the present disclosure. The method may include: polishing a chuck body to form a polished surface, wherein the chuck body is formed from silicon carbide, wherein the chuck body includes an unpolished surface, a plurality of sealing rings, a plurality of vacuum holes, and the polished surface, wherein the plurality of sealing rings axially extend from the unpolished surface, wherein the plurality of vacuum holes are defined by the unpolished surface, wherein the polished surface is a top surface of the chuck body, wherein the polished surface is defined by at least the plurality of sealing rings; depositing a carbon coating on the chuck body, wherein the carbon coating is deposited on the polished surface, wherein the carbon coating has a thickness equal to or less than ten micrometers; and adhering together the chuck body and a bottom cover by an adhesive layer after the carbon coating is deposited on the chuck body.

It is to be understood that both the foregoing general description and the following detailed description are exemplary and explanatory only and are not necessarily restrictive of the present disclosure. The accompanying drawings, which are incorporated in and constitute a part of the specification, illustrate subject matter of the disclosure. Together, the description and drawings serve to explain the principles of the disclosure.

### BRIEF DESCRIPTION OF THE DRAWINGS

The numerous advantages of the disclosure may be better understood by those skilled in the art by reference to the accompanying figures in which:

FIG. 1A illustrates a top perspective view of a vacuum chuck with a closeup view of a sealing ring, rounded bumps, a pin seal, and a lifting pin thereof, in accordance with one or more embodiments of the present disclosure.

FIG. 1B illustrates a cross-section view A-A of FIG. 1A including a carbon coating, in accordance with one or more embodiments of the present disclosure.

FIG. 1C illustrates a bottom perspective view of the vacuum chuck, in accordance with one or more embodiments of the present disclosure.

FIG. 1D illustrates an exploded view of the vacuum chuck, in accordance with one or more embodiments of the present disclosure.

FIG. 2 illustrates a bar graph of experimental results, in accordance with one or more embodiments of the present disclosure.

FIG. 3 illustrates a simplified block diagram of an inspection system including the vacuum chuck, in accordance with one or more embodiments of the present disclosure.

FIG. 4 illustrates a flow diagram of a method of assembling the vacuum chuck, in accordance with one or more embodiments of the present disclosure.

FIG. 5A-5E illustrates a cross-section view of the vacuum chuck during assembly, in accordance with one or more embodiments of the present disclosure.

### DETAILED DESCRIPTION

The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure. Reference will now be made in detail to the subject matter disclosed, which is illustrated in the accompanying drawings.

Embodiments of the present disclosure are directed to a carbon coated silicon carbide vacuum wafer chuck to control electrostatic discharge to wafer. A vacuum chuck may include a chuck body formed from silicon carbide. A carbon coating, such as a diamond-like carbon coating, may be deposited on the chuck body. Coating the silicon carbide vacuum chucks with the carbon coatings may control electrostatic discharge events. The carbon coatings may increase the surface resistance of the chuck body and bring the vacuum chucks to within an electrostatic discharge specification which is a tightening specification in the semiconductor industry.

U.S. Pat. No. 6,678,143B2, titled “Electrostatic chuck and method of manufacturing the same”; U.S. Pat. No. 7,292,427B1, titled “Pin lift chuck assembly for warped substrates”; U.S. Pat. No. 7,607,647B2, titled “Stabilizing a substrate using a vacuum preload air bearing chuck”; U.S. Pat. No. 8,253,119B1, titled “Well-based dynamic pattern generator”; U.S. Pat. No. 9,025,305B2, titled “High surface resistivity electrostatic chuck”; U.S. Pat. No. 9,543,187B2, titled “Electrostatic chuck”; U.S. Pat. No. 9,721,821B2, titled “Electrostatic chuck with photo-patternable soft protrusion contact surface”; U.S. Pat. No. 9,960,070B2, titled “Chucking warped wafer with bellows”; U.S. Pat. No. 10,395,963B2, titled “Electrostatic chuck”; U.S. Pat. No. 11,121,019B2, titled “Slotted electrostatic chuck”; U.S. Pat. No. 11,430,687B2, titled “Vacuum hold-down apparatus for flattening bowed semiconductor wafers”; U.S. Pat. No. 11,612,972B2, titled “Electrostatic chuck with embossments that comprise diamond-like carbon and deposited silicon-based material, and related methods”; U.S. Pat. No. 11,794,314B2, titled “Quick swap chuck with vacuum holding interchangeable top plate”; U.S. Pat. No. 11,842,918B2, titled “Wafer chuck, method for producing the same, and exposure apparatus”; U.S. Patent Publication Number US20140168758A1, titled “Carbon as grazing incidence euv mirror and spectral purity filter”; U.S. Patent Publication Number US20230274967A1, titled “Electrostatic chuck with a charge dissipation structure”; U.S. Patent Publication Number US20240170318A1, titled “Teaching Substrate for Production and Process-Control Tools”; U.S. Patent Publication Number US20240377758A1, titled “Metrology of nanosheet surface roughness and profile”; are each incorporated herein by reference in the entirety.

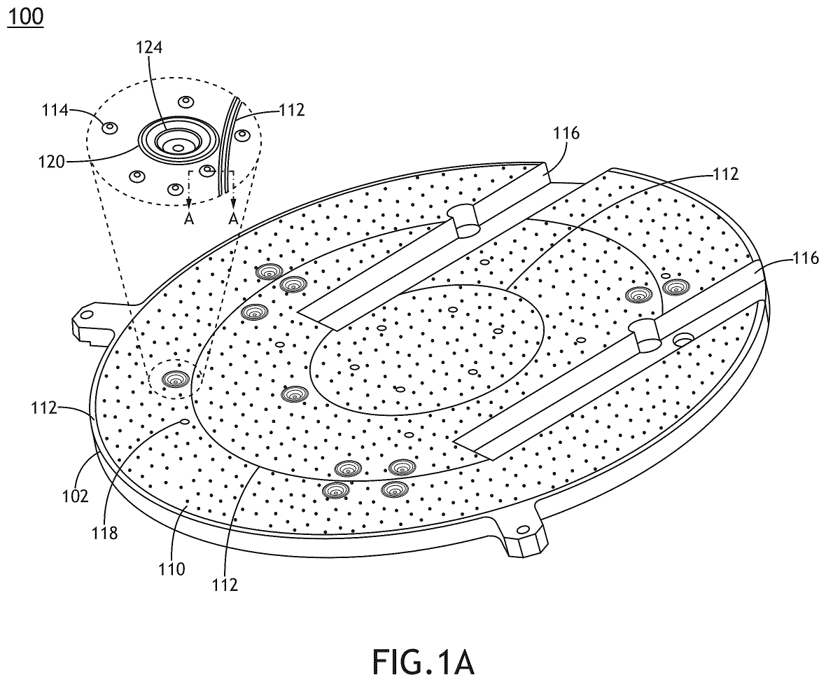

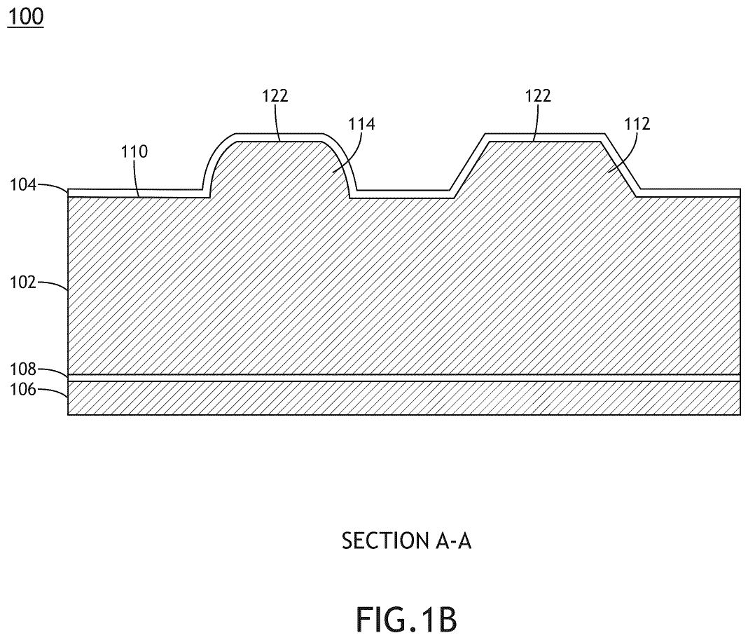

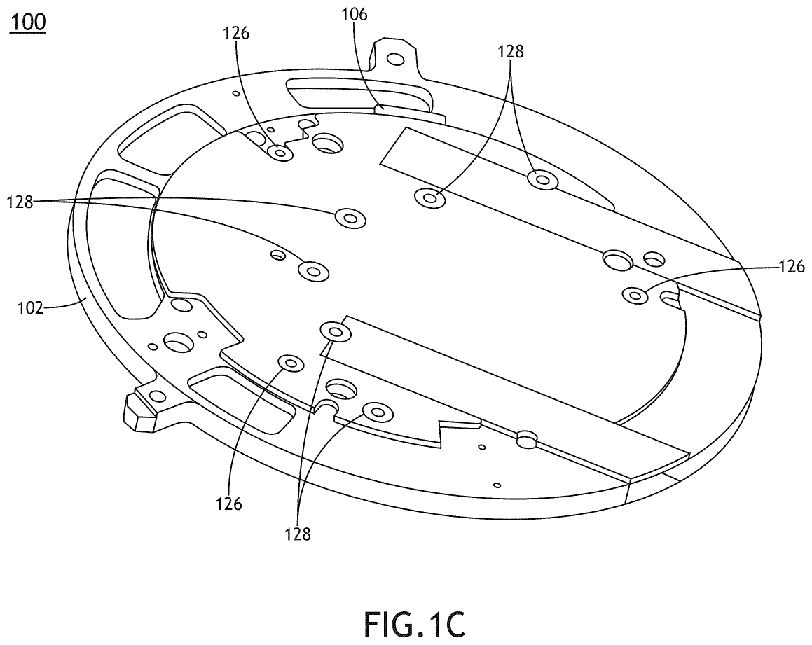

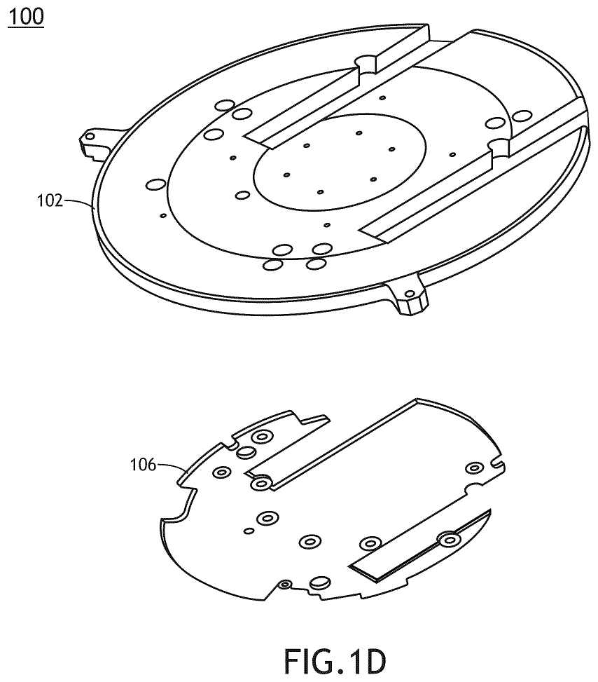

FIGS. 1A-1D illustrate a vacuum chuck 100, in accordance with one or more embodiments of the present disclosure. The vacuum chuck 100 may include a chuck body 102, a carbon coating 104, a bottom cover 106, an adhesive layer 108, and/or lift pins 124.

The chuck body 102 may include an unpolished surface 110, sealing rings 112, rounded bumps 114, slots 116, vacuum holes 118, pin seals 120, a polished surface 122, and/or standoffs 126. The unpolished surface 110, the sealing rings 112, the rounded bumps 114, the slots 116, the vacuum holes 118, the pin seals 120, and/or the polished surface 122 may be disposed on a top side of the chuck body 102. The standoffs 126 may be disposed on a bottom side of the chuck body 102.

The sealing rings 112, the rounded bumps 114, and/or the pin seals 120 may axially extend from the unpolished surface 110. The sealing rings 112, the rounded bumps 114, and/or the pin seals 120 may each include select thicknesses. For example, the thicknesses of the sealing rings 112, the rounded bumps 114, and/or the pin seals 120 may be between 0.1 mm and 0.5 mm.

The chuck body 102 may include a plurality of the sealing rings 112. For example, the chuck body 102 is illustrated with three of the sealing rings 112, although this is not intended to be limiting. The sealing rings 112 may define regions which may each be vacuum sealed. The sealing rings 112 may be concentric to a center axis of the chuck body 102.

The chuck body 102 may include a plurality of the rounded bumps 114. For example, the chuck body 102 may include tens, hundreds, thousands, or more of the rounded bumps 114. The rounded bumps 114 may be distributed across (e.g., radially and circumferentially distributed across) the unpolished surface 110. The rounded bumps 114 may be disposed radially inwards of respective of the sealing rings 112. A top of the rounded bumps 114 may be truncated by the polished surface 122, such that the rounded bumps 114 may be truncated hemispheres. The rounded bumps 114 may be distributed with a select pattern. For example, the rounded bumps 114 may be arranged in a polar array (not depicted) about the center axis of the chuck body 102.

The vacuum chuck 100 may include a plurality of the pin seals 120 and a plurality of the lift pins 124. The chuck body 102 may define one or more of the pin seals 120. For example, the chuck body 102 is depicted as defining eleven of the pin seals 120, although this is not intended as a limitation of the present disclosure. The pin seals 120 may be equally spaced around the chuck body 102 or in other patterns. The pin seals 120 may be disposed radially within one or more of the sealing rings 112. Each of the pin seals 120 may be associated with a respective of the sealing rings 112. The lift pins 124 may also be referred to as stress pins. The lift pins 124 may be disposed within and concentric to the pin seals 120. Each of the lift pins 124 may be associated with a respective of the pin seals 120. The lift pins 124 may be configured to axially translate relative to the chuck body 102 through the pin seals 120.

The vacuum holes 118 may also be referred to as vacuum inlets. The chuck body 102 may define one or more of the vacuum holes 118. For example, the chuck body 102 is depicted as defining twelve of the vacuum holes 118, although this is not intended as a limitation of the present disclosure. The vacuum holes 118 may be defined by the unpolished surface 110. The vacuum holes 118 may be disposed radially within one or more of the sealing rings 112. Each of the vacuum holes 118 may be associated with a respective of the sealing rings 112. The vacuum holes 118 may be configured to evacuate gas disposed radially inwards of the sealing rings 112. The gas disposed radially inwards of the sealing rings 112 may be evacuated by respective of the vacuum holes 118. The vacuum holes 118 may be individually able to evacuated. The vacuum holes 118 may be disposed at different radial distances from the center axis of the chuck body 102. The vacuum holes 118 may be configured to distribute vacuum to the area defined radially between the sealing rings 112 and/or the pin seals 120. As depicted, the outer regions defined by the sealing rings 112 have fewer of the vacuum holes 118 than the inner regions. The outer regions defined by the sealing rings 112 may have fewer of the vacuum holes 118 than the inner regions because the outer regions may require a lower flowrate to provide suction and/or due to complications associated with routing internal vacuum channels.

The polished surface 122 may be a top surface of the chuck body 102. The polished surface 122 may be defined by a top surface of the sealing rings 112, the rounded bumps 114, and/or the pin seals 120. The polished surface 122 may also be referred to as a chucking surface. The polished surface 122 may be substantially flat.

The polished surface 122 may have a low degree of flatness, surface roughness, and/or local slope across the radius and/or circumference of the polished surface 122. The polished surface 122 may include a select flatness, surface roughness, and/or local slope, as measured by an interferometer. The flatness of the polished surface 122 may be measured perpendicular to the plane of the polished surface 122 over about 12 mm across the plane. The flatness of the polished surface 122 may be equal to or less than 10 micrometers. For example, the flatness of the polished surface 122 may be equal to or less than four micrometers. The surface roughness may be an arithmetic average roughness (Ra). For example, the surface roughness of the polished surface 122 may be equal to or less than 0.1 micrometers. The local slope may also be referred to as parallelism. The polished surface 122 may include a local slope equal to or less than 100 arcseconds. For example, the local slope of the polished surface 122 may be equal to or less than 25 arcseconds.

The slots 116 may be configured to receive a robot end effector (not shown). The sealing rings 112 may circumferentially extend up to and around the slots 116 for sealing the slots 116. Thus, the sealing rings 112 may seal the slots 116.

The chuck body 102 may include one or more of the standoffs 126. For example, the chuck body 102 is depicted with three of the standoffs 126, although this is not intended as a limitation of the present disclosure. The standoffs 126 may be disposed on an opposite side of the chuck body 102 as the unpolished surface 110, the sealing rings 112, the rounded bumps 114, the slots 116, the vacuum holes 118, the pin seals 120, and/or the polished surface 122.

The bottom cover 106 may be disposed below the chuck body 102. The standoffs 126 may axially extend through the bottom cover 106.

The bottom cover 106 may include vacuum pads 128. The bottom cover 106 may include a plurality of the vacuum pads 128. For example, the bottom cover 106 is depicted with six of the vacuum pads 128, although this is not intended as a limitation of the present disclosure. The vacuum pads 128 may fluidically couple with the vacuum holes 118. The bottom cover 106 may cover one or more vacuum channels (not depicted) defined by the chuck body 102. The vacuum channels may fluidically couple the vacuum holes 118 and the vacuum pads 128.

The chuck body 102 and/or the bottom cover 106 may be formed from a ceramic material. The ceramic material may include silicon carbide. For example, the chuck body 102 and/or the bottom cover 106 may be a mixture of silicon and silicon carbide. For instance, the chuck body 102 and/or the bottom cover 106 may be a mixture 20% silicon and 80% silicon carbide by weight (e.g., RB010-SiC (Si-SiC 20/80%) commercially available from Nano-Solutions™). Advantages of making the chuck body 102 and/or the bottom cover 106 from silicon carbide or a mixture thereof, as compared to making from aluminum or an alloy thereof, may be that the chuck body 102 and/or the bottom cover 106 may exhibit high performance in regards to stiffness and low coefficient of thermal expansion. Thus, the surface roughness and/or the local slope of the polished surface 122 may not substantially change with temperature.

The adhesive layer 108 may adhere together the chuck body 102 and the bottom cover 106. The adhesive layer 108 may adhere together the chuck body 102 and the bottom cover 106 by surface attachment. The adhesive layer 108 may include any suitable adhesive material, such as, but not limited to, an epoxy. The epoxy may be a low stress, low outgassing epoxy.

The carbon coating 104 may be deposited on the chuck body 102. For example, the carbon coating 104 may be deposited on the unpolished surface 110, the sealing rings 112, the rounded bumps 114, the slots 116, the vacuum holes 118, the pin seals 120, and/or the polished surface 122 of the chuck body 102. In embodiments, the carbon coating 104 may be deposited on at least the sealing rings 112, the rounded bumps 114, the pin seals 120, and/or the polished surface 122. The carbon coating 104 may additionally be deposited on the unpolished surface 110, the slots 116, and/or the vacuum holes 118, of the chuck body 102. The carbon coating 104 may be deposited on the top of the chuck body 102. The carbon coating 104 may be the topmost surface of the vacuum chuck 100.

The carbon coating 104 may be a high-density carbon material. The carbon coating 104 may be amorphous carbon and may contain a mixture of both Sp2 and Sp3 carbon-carbon interatomic bonds. The high-density carbon material may be carbon having a specific gravity of at least 2.0 g/cm2 and has an Sp2/Sp3 ratio of between 0 and 3. An Sp2 bond (π) is an asymmetrical carbon-carbon bond employing Sp2 orbitals of the carbons. An Sp3 bond (σ) is a symmetrical carbon-carbon bond employing an Sp3 hybrid orbital of each carbon atom. By adjusting the deposition conditions, the relative ratio (π/σ) of Sp2 bond (π) and Sp3 bond (σ), the physical properties such as optical constants (n & k), thermal conductivity, electrical conductivity, mechanical strength, and roughness of the high-density carbon can be adjusted. Higher Sp3 content may make the films more diamond like, while higher contents of Sp2 in carbon film make it more graphitic or amorphous.

In embodiments, the high-density carbon material of the carbon coating 104 may be a diamond-like carbon (DLC) material. The diamond-like carbon may be hydrogen-free or hydrogenated. The diamond-like carbon may or may not include a metal. The diamond-like carbon may be deposited in various morphologies and crystalline structures. Such structures include, but are not limited to, amorphous carbon, crystalline carbon, graphite, and/or tetrahedral-carbon (ta-C) containing films. For example, the diamond-like carbon may be any of a hydrogen-free amorphous carbon film, a tetrahedral hydrogen-free amorphous carbon film, a metal-containing hydrogen-free amorphous carbon film, a hydrogenated amorphous carbon film, a tetrahedral hydrogenated amorphous carbon film, a metal-containing hydrogenated amorphous carbon film, or a modified hydrogenated amorphous carbon film. The diamond-like carbon material may include an Sp2/Sp3 bond ratio of between 1.5 and 1.7.

The carbon coating 104 may include a select thickness. The thickness of the carbon coating 104 may be equal to or less than 10 micrometers. For example, the thickness of the carbon coating 104 may be between 2 micrometers and 4 micrometers. For instance, the thickness of the carbon coating 104 may be between 2 micrometers and 3 micrometers. The maximum and minimum values for the thickness for the carbon coating 104 may be selected to prevent delamination and achieve a sufficient lifetime for the carbon coating 104. If the thickness is too low, the carbon coating 104 may experience wear such that the lifetime of the carbon coating 104 may be less than the vacuum chuck 100. If the thickness is too high, the carbon coating 104 may be prone to delamination due to differing coefficients of thermal expansion. In embodiments, the thicknesses of the sealing rings 112, the rounded bumps 114, and/or the pin seals 120 may be two orders of magnitude larger than the thickness of the carbon coating 104.

The carbon coating 104 may have a select surface resistance. The carbon coating 104 may act as a semiconductor and/or a dissipative conductor. The carbon coating 104 may reduce or drain charge that builds up on the chuck body 102 while being of sufficiently high resistance to prevent electrostatic discharge. For example, the carbon coating 104 may have a surface resistance of greater than or equal to 10\hat{ }5 Ω/sq and less than 10\hat{ }11 Ω/sq. For instance, the carbon coating 104 may have a surface resistance of greater than or equal to 10\hat{ }6 Ω/sq and less than 10\hat{ }10 Ω/sq. The carbon coating 104 may be beneficial to increase the surface resistance of the chuck body 102. For example, the surface resistance of the carbon coating 104 may be several orders of magnitude larger than the surface resistance of the silicon carbide material of the chuck body 102. The increase of surface resistance is achieved due to the material of the carbon coating 104 and/or the thickness of the carbon coating 104.

The carbon coating 104 may be a region of material having the thickness and the composition which provides a select electrical resistance. The carbon coating 104 may be robust enough to meeting lifetime requirements. The carbon coating 104 may also provide good adhesion with the silicon carbide base material. Additionally, the carbon coating 104 may not affect the flatness, the surface roughness, and/or the local slope of the polished surface 122. The carbon coating 104 coating may also include favorable properties, including hardness, wear resistance, low coefficient of friction, and the like.

The carbon coating 104 may not fill the vacuum holes 118. For example, the diameter of the vacuum holes 118 may be several orders of magnitude larger than the thickness of the carbon coating 104. The carbon coating 104 may also be sufficiently thin to not prevent the axial translation of the lift pins 124.

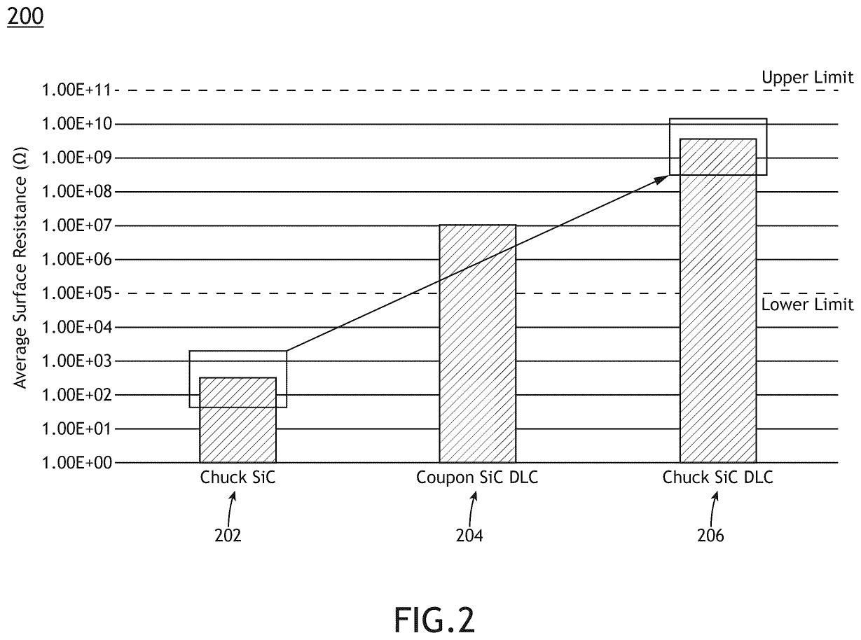

FIG. 2 illustrates a bar graph 200 of experimental results, in accordance with one or more embodiments of the present disclosure. In this bar graph 200, three groups of samples were analyzed. The groups of samples which were analyzed included a first group 202 (Chuck SiC), a second group 204 (Coupon SiC DLC), and a third group 206 (Chuck SiC DLC). The first group 202 includes the chuck body 102 formed of silicon carbide without the carbon coating 104. The second group 204 includes a coupon of silicon carbide with the carbon coating 104 deposited overtop. The third group 206 includes the vacuum chuck 100 with the chuck body 102 formed of silicon carbide and with the carbon coating 104 deposited overtop. The y-axis of the bar graph 200 indicates the average surface resistance (Q/sq) of the first group 202, the second group 204, and the third group 206. The y-axis of the bar graph 200 is a logarithmic scale from 1 Ω/sq to 10\hat{ }11 Ω/sq. The first group 202 was found to have a surface resistance value of 3.49×10\hat{ }2 Ω/sq with a standard deviation of 1.33×10\hat{ }2 Ω/sq. The third group 206 was found to have a surface resistance value of 3.91×10\hat{ }9 Ω/sq with a standard deviation of 3.00×10\hat{ }2 Ω/sq. Thus, the carbon coating 104 may increase the surface resistance of the vacuum chuck 100 and cause the surface resistance to be greater than or equal to 10\hat{ }5 Ω/sq and less than 10\hat{ }11 Ω/sq.

The surface resistance is a probe dependent measurement. The surface resistance depends on the geometry of the probe as wells as the contact of the probe and the surface. Three probe types were used. The probe types included a Desco™ 19297 probe, a Prostat™ PRF-922B with rubber boots, and a Prostat™ PRF-922B without rubber boots. One probe type was found to be one order of magnitude higher than the other two probe types. Because surface resistance is a probe dependent measurement which is not normalized by probe geometry compared to surface resistivity, measurements with several surface resistance probes were taken to verify the DLC coated SiC wafer chuck is within specification for a variety of probe types. Several chuck surfaces were measured to determine the variability of surface resistance measurements across different wafer chuck surfaces.

The sealing rings 112, the rounded bumps 114, the pin seals 120, and/or the polished surface 122 are designed to have a low contact area as possible and are not conducive to generate surface resistance measurements directly on those surfaces. Instead, the surface resistance was measured on the portion of the carbon coating 104 deposited on the unpolished surface 110 disposed between the rounded bumps 114. The probe may be sufficiently small to fit between adjacent of the rounded bumps 114. Notably, the carbon coating 104 over the unpolished surface 110 may appear visually different than the carbon coating 104 over the polished surface 122, without impacting the surface resistance.

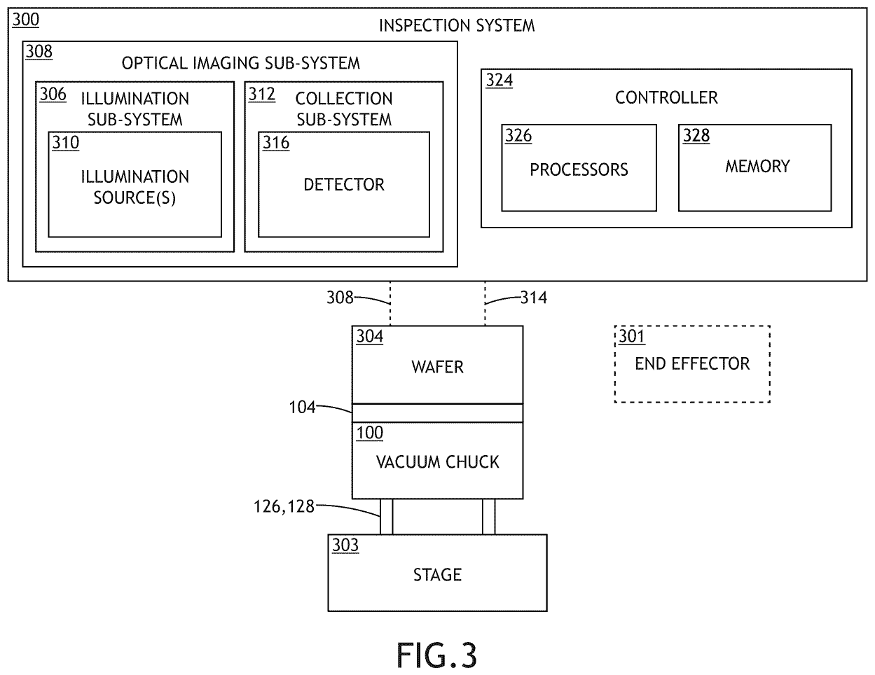

FIG. 3 illustrates an inspection system 300, in accordance with one or more embodiments of the present disclosure. The inspection system 300 may include the vacuum chuck 100.

The vacuum chuck 100 may be configured to chuck a wafer 304. The wafer 304 may be chucked onto the sealing rings 112, the rounded bumps 114, the pin seals 120, and/or the polished surface 122 via a vacuum with the carbon coating 104 abutting therebetween. To chuck the wafer 304, the lift pins 124 may be axially translated up to a backside of the wafer 304 and suctioned to the backside. The lift pins 124 may then be axially translated downwards to pull the backside of the wafer 304 against the sealing rings 112, the rounded bumps 114, the pin seals 120, and/or the polished surface 122 with the carbon coating 104 abutting therebetween. The vacuum holes 118 may then evacuate the gas disposed between the sealing rings 112 to chuck the wafer 304 via the vacuum. The vacuum holes 118 may be configured to evacuate the gas which is disposed radially inwards of the sealing rings 112 and axially disposed between the backside of the wafer 304 and the unpolished surface 110. The evacuation of the gas may apply a chucking force on the wafer 304. Disposing the vacuum holes 118 at different radial distances may allow the vacuum chuck 100 to secure wafers of different sizes (e.g., 200-mm wafers and 300-mm wafers). The rounded bumps 114 may reduce contact stress with the backside of a wafer secured by the vacuum chuck 100. The rounded bumps 114 may be distributed to reduce or eliminate local slope variations at the front surface of the wafer secured by vacuum chuck 100. To un-chuck the wafer 304, the lift pins 124 may axially translate upwards to release the vacuum seal between the wafer 304 and the vacuum chuck 100 and allow gas to flow radially inwards of the sealing rings 112. The placement, number, or grouping of the vacuum holes 118 and/or the lift pins 124 may be optimized for a particular wafer. For example, the diameter, the thickness, the stiffness, the warpage, the shape, and/or the surface finish of the wafer 304 may affect the placement, the number, and/or the grouping of the vacuum holes 118 and/or the lift pins 124.

The carbon coating 104 may abut the bottom surface of the wafer 304. The surface resistance of the carbon coating 104 may be a safe range to dissipate any residual potential difference slowly enough to not cause damage to the wafer 304. The surface resistance may be sufficiently low to allow dissipating charge between the wafer 304 and the chuck body 102. The surface resistance may also be sufficiently high to prevent electrostatic discharge between the wafer 304 and the chuck body 102. The carbon coating 104 may also control the resistance-to-ground for the wafer 304.

The inspection system 300 may include a stage 303. The stage 303 may be a moveable stage. The stage 303 may be coupled to and configured to move the vacuum chuck 100. For example, the vacuum chuck 100 may be coupled to the stage using the standoffs 126. The stage 303 may be configured to translate the vacuum chuck 100 in an X-direction and/or a Y-direction. The stage 303 may also be coupled to the vacuum pads 128. The stage 303 may include a source of vacuum coupled to the vacuum pads 128. The stage 303 may be configured to suction gas through the vacuum holes 118 via the vacuum pads 128. The stage 303 may also be configured to axially translate the lift pins 124.

The inspection system 300 may include an end effector 301 which may be configured to transfer the wafer 304 to and from the vacuum chuck 100 using the slots 116. The end effector 301 may be a type that may grip the wafer 304 from a backside thereof (e.g., using vacuum pads). The end effector 301 may place the wafer 304 onto and remove the wafer 304 from the vacuum chuck 100, while translating through the slots 116. The slots 116 may be configured to receive the end effector 301.

The wafer 304 may be any type of wafer. For example, the wafer 304 may be a semiconductor wafer or another type of wafer, such as those used to manufacture LEDs, solar cells, magnetic discs, flat panels, or polished plates. The wafer 304 that may be generally circular, generally rectangular, or other shapes. For example, the wafer 304 may be a generally circular semiconductor wafer. The wafer 304 may also have a select size. In embodiments, wafer 304 has dimensions conforming to that of a Semiconductor Equipment and Materials International (SEMI®) wafer. For example, the wafer 304 may have a diameter such as 100 mm, 200 mm, 300 mm, or 450 mm and a thickness from 0.5 mm to 1.0 mm. For instance, the wafer 304 may be a 300 mm notched wafer. In other examples, the wafer 304 may be a generally rectangular solar cell that has dimensions from approximately 100 mm to 200 mm square and a thickness from approximately 0.15 mm to 0.30 mm.

The wafer 304 may include a substrate formed of a semiconductor or non-semiconductor material (e.g., a wafer, or the like). For example, a semiconductor or non-semiconductor material may include, but is not limited to, monocrystalline silicon, gallium arsenide, and indium phosphide. The wafer 304 may further include one or more layers disposed on the substrate. For example, such layers may include, but are not limited to, a resist, a dielectric material, a conductive material, and a semiconductive material. Many different types of such layers are known in the art, and the term wafer as used herein is intended to encompass a sample on which all types of such layers may be formed. One or more layers formed on the wafer 304 may be patterned or un-patterned. For example, the wafer 304 may include a plurality of dies, each having repeatable patterned features. Formation and processing of such layers of material may ultimately result in completed devices. Many different types of devices may be formed on the wafer 304, and the term sample as used herein is intended to encompass a sample on which any type of device known in the art is being fabricated.

The inspection system 300 may be configured to inspect the wafer 304. In the field of semiconductor metrology, the inspection system 300 may include an optical imaging sub-system 302. The optical imaging sub-system 302 may include an illumination sub-system 306 which illuminates a target and a collection sub-system 312 which captures relevant information provided by the interaction (or lack thereof) of the illumination sub-system 306 with a target, device, or feature. The inspection system 300 may also include a controller 324 (e.g., a processing system) which analyzes the information collected using one or more algorithms.

The inspection system 300 may include any type of metrology system known in the art suitable for providing metrology signals associated with metrology targets on the wafer 304. The optical imaging sub-system 302 can comprise one or more hardware configurations. For example, the optical imaging sub-system 302 may include, but is not limited to, a spectrometer, a spectroscopic ellipsometer with one or more angles of illumination, a spectroscopic ellipsometer for measuring Mueller matrix elements (e.g., using rotating compensators), a single-wavelength ellipsometer, an angle-resolved ellipsometer (e.g., a beam-profile ellipsometer), a spectroscopic reflectometer (e.g., broadband reflective spectrometer), a single-wavelength reflectometer, an angle-resolved reflectometer (e.g., a beam-profile reflectometer), a pupil imaging system, a spectral imaging system, or a scatterometer (e.g. speckle analyzer). The hardware configurations can be separated into discrete operational systems. On the other hand, one or more hardware configurations can be combined into the inspection system 300. For example, multiple metrology heads may be integrated in the inspection system 300.

In one embodiment, the inspection system 300 is configured to provide spectroscopic signals indicative of one or more optical properties of a metrology target (e.g., one or more dispersion parameters, and the like) at one or more wavelengths. In one embodiment, the inspection system 300 includes an image-based metrology tool to measure metrology data based on the generation of one or more images of the wafer 304. In another embodiment, the inspection system 300 includes a scatterometry-based metrology system to measure metrology data based on the scattering (reflection, diffraction, diffuse scattering, and the like) of light from the wafer 304.

In one embodiment, the inspection system 300 includes one or more of the optical imaging sub-system 302 (e.g., optical imaging tools). In some embodiments, the inspection system 300 may include a single of the optical imaging sub-system 302 or multiple of the optical imaging sub-system 302. Where the inspection system 300 is a spectroscopic imaging system, the multiple of the optical imaging sub-system 302 of the spectroscopic imaging system may include a broadband spectroscopic ellipsometer, a spectroscopic ellipsometer with rotating compensator, a beam profile ellipsometer, a beam profile reflectometer, a broadband reflective spectrometer, a deep ultra-violet reflective spectrometer, and the like. It is further contemplated that the optical imaging sub-system 302 include numerous optical elements in such systems, including certain lenses, collimators, mirrors, quarter-wave plates, polarizers, detectors, cameras, apertures, and/or light sources.

The one or more of the optical imaging sub-system 302 are configured to generate one or more images of a wafer 304. For example, the optical imaging sub-system 302 may include an illumination sub-system 306 configured to illuminate the wafer 304 with illumination 308 from illumination sources 310 and a collection sub-system 312 configured to generate an image of the wafer 304 in response to light emanating from the wafer 304 (e.g., sample light 314) the illumination 308 using a detector 316.

The illumination sub-system 306 includes illumination sources 310. Examples of suitable light sources are: a white light source, an ultraviolet (UV) laser, an arc lamp or an electrode-less lamp, a laser sustained plasma (LSP) source, a supercontinuum source (such as a broadband laser source), or shorter-wavelength sources such as x-ray sources, extreme UV sources, or some combination thereof.

The illumination sources 310 may generate illumination 308. The illumination 308 may have only one wavelength (i.e., monochromatic light), several discrete wavelengths (i.e., polychromatic light), multiple wavelengths (i.e., broadband light) and/or sweeps through wavelengths, either continuously or hopping between wavelengths (i.e., tunable sources or swept source). The illumination 308 may be polarization-resolved, unpolarized, or the like.

The illumination sources 310 may include any type of illumination source known in the art suitable for generating the illumination 308, which may be in the form of one or more illumination beams. Further, the illumination 308 may have any spectrum such as, but not limited to, extreme ultraviolet (EUV) wavelengths, ultraviolet (UV) wavelengths, visible wavelengths, or infrared (IR) wavelengths. Further, the illumination sources 310 may be a broadband source, a narrowband source, and/or a tunable source. In some embodiments, the illumination sources 310 includes a broadband plasma (BBP) illumination source. In this regard, the illumination 308 may include radiation emitted by a plasma. Further, at least a portion of the plasma radiation may be utilized as the illumination 308. In another embodiment, the illumination sources 310 may include one or more lasers. For instance, the illumination sources 310 may include any laser system known in the art capable of emitting radiation in the infrared, visible, or ultraviolet portions of the electromagnetic spectrum. The illumination 308 may have any temporal profile. For example, the illumination 308 may include continuous-wave (CW) illumination, pulsed illumination, or modulated illumination. Additionally, the illumination 308 may be delivered from the illumination sources 310 via free-space propagation or guided light (e.g., an optical fiber, a light pipe, or the like).

The illumination sub-system 306 and/or the optical imaging sub-system 302 may include various components to direct the illumination 308 to the wafer 304 such as, but not limited to, lenses, mirrors, or the like. Further, such components may be reflective elements or transmissive elements. The illumination sub-system 306 may further include one or more optical elements to modify and/or condition light in the associated optical path such as, but not limited to, one or more polarizers, one or more filters, one or more beam splitters, one or more diffusers, one or more homogenizers, one or more apodizers, or one or more beam shapers. In embodiments, the illumination sub-system 306 and/or the optical imaging sub-system 302 includes a beam-splitter oriented to simultaneously direct the illumination 308 to the wafer 304 and collect sample light 314 emanating from the wafer 304. In this regard, the illumination 308 and the sample light 314 may share the same path between the beam-splitter and the wafer 304.

The optical imaging sub-system 302 may include various components to collect at least a portion of the sample light 314 radiation emanating from the wafer 304 (e.g., sample light in the case of an optical imaging sub-system 302) and direct at least a portion of the sample light 314 to a detector 316 for generation of an image. The collection sub-system 312 may further include any number of collection beam conditioning elements to direct and/or modify illumination collected including, but not limited to one or more lenses, one or more filters, one or more polarizers, or one or more phase plates. In this regard, the optical imaging sub-system 302 may be configured as any type of metrology tool such as, but not limited to, a spectroscopic ellipsometer with one or more angles of illumination, a spectroscopic ellipsometer for measuring Mueller matrix elements (e.g., using rotating compensators), a single-wavelength ellipsometer, an angle-resolved ellipsometer (e.g., a beam-profile ellipsometer), a spectroscopic reflectometer, a single-wavelength reflectometer, an angle-resolved reflectometer (e.g., a beam-profile reflectometer), an imaging system, a pupil imaging system, a spectral imaging system, or a scatterometer.

In another embodiment, the optical imaging sub-system 302 includes a detector 316 configured to capture radiation emanating from the wafer 304 through the collection pathway. For example, a detector 316 may receive radiation reflected or scattered (e.g., via specular reflection, diffuse reflection, and the like) from the wafer 304. By way of another example, a detector 316 may receive radiation generated by the wafer 304 (e.g., luminescence associated with absorption of the illumination 308, and the like). By way of another example, a detector 316 may receive one or more diffracted orders of radiation from the wafer 304 (e.g., 0-order diffraction, ±1 order diffraction, ±2 order diffraction, and the like). The detector 316 may include any type of sensor known in the art suitable for measuring sample light 314. For example, a detector 316 may include a multi-pixel sensor such as, but not limited to, a charge-couple device (CCD), a complementary metal-oxide-semiconductor (CMOS) device, a line sensor, or a time-delay-integration (TDI) sensor. As another example, a detector 316 may include two or more single-pixel sensors such as, but not limited to, a photodiode, an avalanche photodiode, a photomultiplier tube, or a single-photon detector. In some embodiments, the detector 316 may include the TDI sensor. The TDI sensor may include multiple pixel rows and a readout row. The TDI sensor may include clocking signals that successively move charge from one pixel row to the next until the charge reaches the readout row, where a row of the image is generated. By synchronizing the charge transfer (e.g., based on the clocking signals) to the motion of the wafer 304 along the scan direction, charge may continue to build up across the pixel rows to provide a relatively higher signal to noise ratio compared to a line sensor.

The optical imaging sub-system 302 may generate one or more images of the wafer 304 using any technique known in the art. In some embodiments, the illumination sources 310 is an optical source configured to generate illumination 308 in the form of light, and where the collection sub-system 312 images the wafer 304 based on light emanating from the wafer 304. The inspection system 300 may further image the wafer 304 using any technique known in the art. In some embodiments, the inspection system 300 generates an image of the wafer 304 in a scanning mode by focusing the illumination 308 onto the wafer 304 as a spot or a line, capturing a point or line image, and scanning the wafer 304 to build up a two-dimensional image. In this configuration, scanning may be achieved by moving the wafer 304 with respect to the illumination 308, by moving the illumination 308 with respect to the wafer 304 (e.g., using actuatable mirrors, or the like), or a combination thereof. The scanning may include scanning the wafer 304 along a scan path to generate a swath of the scan path. In some embodiments, the inspection system 300 generates an image of the wafer 304 in a static mode by directing the illumination 308 to the wafer 304 in a two-dimensional field of view and capturing a two-dimensional image directly with the detector 316.

An image generated by the inspection system 300 may be any type of image known in the art such as, but not limited to, a brightfield image, a darkfield image, a phase-contrast image, or the like. In some embodiments, the images may be raw images from the optical imaging sub-system 302. In this configuration, the inspection images may include various patterned features on the wafer 304. Further, images may be stitched together to form a composite image of the wafer 304 or a portion thereof, although this is not intended as a limitation of the present disclosure. Although the images have been described as including the patterned features, this is not intended as a limitation of the present disclosure. It is further contemplated that the images may be from the wafer 304 with no patterned features.

The optical imaging sub-system 302 may provide various types of measurements related to semiconductor manufacturing. For example, the optical imaging sub-system 302 may provide one or more metrology metrics of one or more metrology targets such as, but not limited to, a metrology metric. In this regard, the optical imaging sub-system 302 may also be referred to as a metrology tool. The metrology metric may include, but is not limited to, structural and material characteristics of the wafer 304, bandgap, critical dimensions (e.g., widths of fabricated features at a selected height), overlay of two or more layers, sidewall angles, film thicknesses, or process-related parameters (e.g., focal position of the wafer 304 during a lithography step, an exposure dose of illumination during a lithography step, and the like). The structural characteristics of the wafer 304 may include, but are not limited to, dimensional characteristics of structures and films such as film thickness and/or critical dimensions of structures, overlay, etc.) associated with various semiconductor fabrication processes. The material characteristics may include, but are not limited to, material composition associated with various semiconductor fabrication processes. The metrology metrics are used to facilitate process controls and/or yield efficiencies in the manufacture of semiconductor dies. It is recognized herein that semiconductor processes (e.g., deposition of a film, a lithography step, an etch step, and the like) performed by a semiconductor process tool may drift over time. Drift may be a result of a multitude of factors including, but not limited to, tool wear or drift in a control algorithm associated with the process. Further, the drift may affect one or more characteristics of the wafer 304, which may, in turn, affect one or more metrology measurements (e.g., the metrology metric proportional to the bandgap, a critical dimension measurement, and the like). In this regard, metrology measurements may provide diagnostic information associated with one or more steps in a fabrication process. Metrology data may be utilized in the semiconductor manufacturing process for example to feed-forward, feed-backward and/or feed-sideways corrections to the process (e.g., a lithography step, an etch step, and the like) to provide a complete process-control solution.

In some embodiments, the inspection system 300 includes the controller 324. The optical imaging sub-system 302 is communicatively coupled to the controller 324. In this regard, the controller 324 may be configured to receive data including, but not limited to, metrology data (e.g., spectroscopic signals, images of the target, pupil images, and the like) or metrology metrics (e.g., a metrology metric proportional to a bandgap of a multilayer grating, critical dimensions, film thickness, composition, overlay precision, tool-induced shift, sensitivity, diffraction efficiency, through-focus slope, side wall angle, and the like). In some embodiments, the metrology data includes an indication of the measured spectral response (e.g., measured intensity as a function of wavelength) of the wafer 304 based on the one or more sampling processes from a spectrometer (e.g., the optical imaging sub-system 302).

The controller 324 may use the data from the optical imaging sub-system 302 in the semiconductor manufacturing process for example to feed-forward, feed-backward and/or feed-sideways corrections to the process (e.g., lithography, etch) and therefore, might yield a complete process control solution.

The controller 324 may include one or more processors 326 configured to execute program instructions maintained on a memory 328 (e.g., a memory medium). In this regard, the one or more processors 326 of controller 324 may execute any of the various process steps described throughout the present disclosure. The controller 324 may be communicatively coupled to the one or more optical imaging sub-system 302. The controller 324 may receive images from the optical imaging sub-system 302. For example, the controller 324 may receive the images from the detector 316.

The one or more processors 326 of a controller 324 may include any processing element known in the art. In this sense, the one or more processors 326 may include any microprocessor-type device configured to execute algorithms and/or instructions. In one embodiment, the one or more processors 326 may consist of a desktop computer, mainframe computer system, workstation, image computer, parallel processor, or any other computer system (e.g., networked computer) configured to execute a program configured to operate the inspection system 300, as described throughout the present disclosure. It is further recognized that the term “processor” may be broadly defined to encompass any device having one or more processing elements, which execute program instructions from a memory 328.

The memory 328 may include any storage medium known in the art suitable for storing program instructions executable by the one or more processors 326. For example, the memory 328 may include a non-transitory memory medium. By way of another example, the memory 328 may include, but is not limited to, a read-only memory, a random-access memory, a magnetic or optical memory device (e.g., disk), a magnetic tape, a solid-state drive, and the like. It is further noted that memory 328 may be housed in a common controller housing with the one or more processors 326. In one embodiment, the memory 328 may be located remotely with respect to the physical location of the one or more processors 326 and controller 324. For instance, the one or more processors 326 of controller 324 may access a remote memory (e.g., server), accessible through a network (e.g., internet, intranet, and the like). Therefore, the above description should not be interpreted as a limitation on the present invention but merely an illustration.

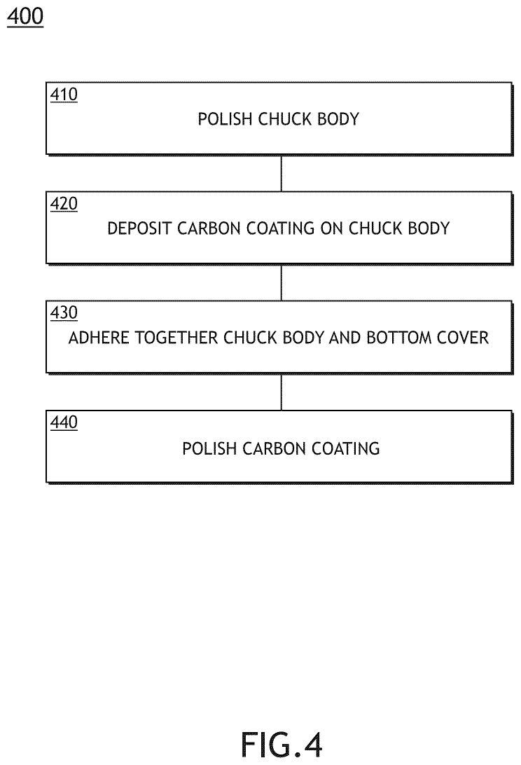

FIG. 4 illustrates a flow diagram of a method 400, in accordance with one or more embodiments of the present disclosure. The method 400 may be a method of manufacturing the vacuum chuck 100. The embodiments and the enabling technologies described previously herein in the context of the vacuum chuck 100 should be interpreted to extend to the method 400. It is further noted, however, that the method 400 is not limited to the architecture of the vacuum chuck 100.

In a step 410, a chuck body may be polished to form a polished surface. For example, the chuck body 102 may be polished may be polished to form the polished surface 122. The top of the sealing rings 112, the rounded bumps 114, and/or the pin seals 120 may be polished to form the polished surface 122. The chuck body 102 may be polished by lapping or the like. Polishing the sealing rings 112, the rounded bumps 114, and/or the pin seals 120 may cause the polished surface 122 to have the select degree of flatness, surface roughness, and/or local slope across the polished surface 122. It may then be desirable to maintain the flatness, surface roughness, and/or local slope across the polished surface 122 through the remainder of the steps of the method 400.

In in a step 420, a carbon coating may be deposited on the chuck body. For example, the carbon coating 104 may be deposited on the chuck body 102. The carbon coating 104 may be deposited on the unpolished surface 110, the sealing rings 112, the rounded bumps 114, the slots 116, the vacuum holes 118, the pin seals 120, and/or the polished surface 122 of the chuck body 102. The carbon coating 104 may be deposited using chemical vapor deposition (CVD), plasma-enhanced chemical vapor deposition (PECVD), physical vapor deposition (PVD), or the like. In embodiments the carbon coating 104 is deposited using plasma-enhanced chemical vapor deposition. The plasma-enhanced chemical vapor deposition may be beneficial to ensure a uniform thickness of the carbon coating 104 without impacting the flatness, surface roughness, and/or local slope across the polished surface 122.

Optionally, the chuck body 102 may be cleaned by an ultrasonic cleaning process before depositing the carbon coating 104. The ultrasonic cleaning process may include blowing out the vacuum holes 118 with nitrogen gas.

In a step 430, an adhesive layer adheres together the chuck body and a bottom cover. For example, the adhesive layer 108 may adhere together the chuck body 102 and the bottom cover 106.

The adhesive layer 108 may adhere together the chuck body 102 and the bottom cover 106 after the carbon coating 104 is deposited on the chuck body 102. During the plasma-enhanced chemical vapor deposition process, temperatures can reach above 100 degrees C. The inventor experimentally determined that the temperature caused the adhesive layer 108 to exhibit plastic deformation, thereby changing the flatness of the polished surface 122. It is contemplated that causing the adhesive layer 108 to adhere together the chuck body 102 and the bottom cover 106 after the carbon coating 104 may maintain the flatness of the polished surface 122 by preventing the plastic deformation of the adhesive layer 108.

In an optional step 440, the carbon coating deposited on the polished surface may be polished. For example, the carbon coating 104 deposited on the polished surface 122 may be polished. Polishing the carbon coating 104 on the polished surface 122 after adhering together the chuck body 102 and the bottom cover 106 may be beneficial to improve the flatness, surface roughness, and/or the local slope across the carbon coating 104. One consideration in polishing the carbon coating 104 may be to maintain the carbon coating 104 between maximum and minimum allowable thicknesses (e.g., below a maximum thickness to prevent delamination before polishing and above a minimum thickness after polishing to ensure the lifetime of the carbon coating 104). Polishing the carbon coating 104 may decrease a thickness of the portions of the carbon coating 104 deposited on the sealing rings 112, the rounded bumps 114, the pin seals 120, and/or the polished surface 122 of the chuck body 102 but may not decrease the thickness of the portions of the carbon coating 104 deposited on the unpolished surface 110, the slots 116, and/or the vacuum holes 118. It may be desirable to ensure the portions of the carbon coating 104 deposited on the sealing rings 112, the rounded bumps 114, the pin seals 120, and/or the polished surface 122 are above the minimum thickness and ensure the portions of the carbon coating 104 deposited on the unpolished surface 110, the slots 116, and/or the vacuum holes 118 are below the maximum thickness.

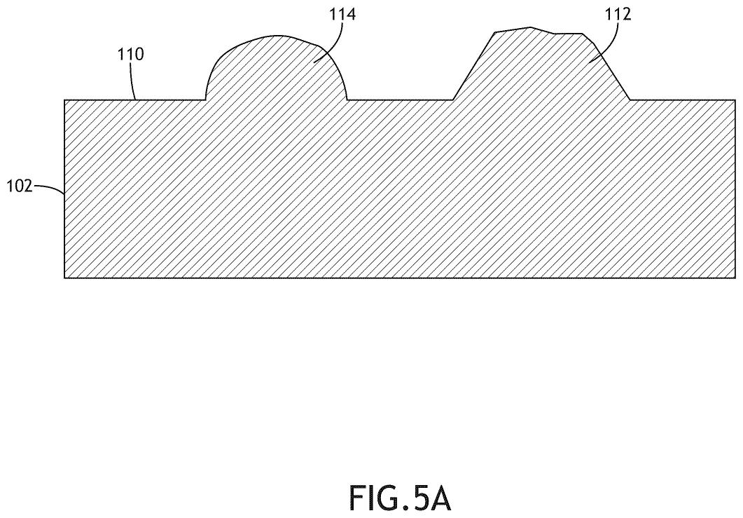

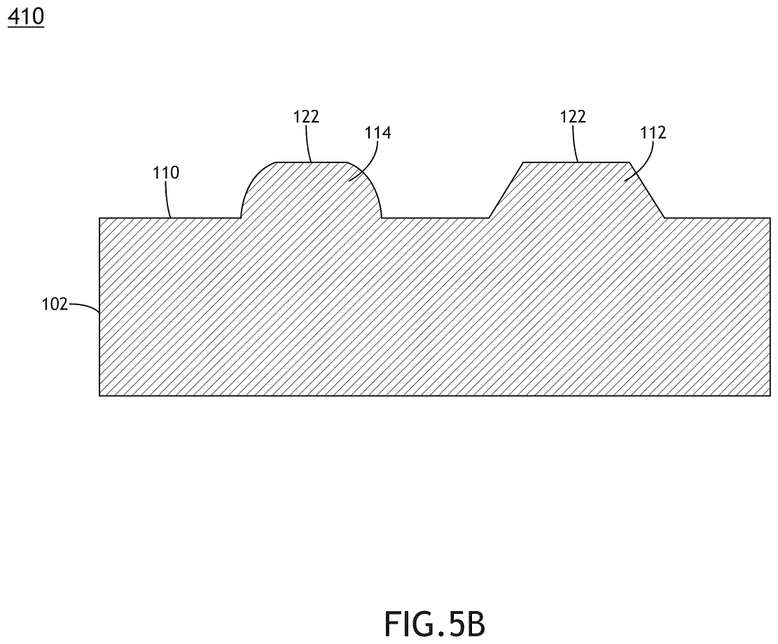

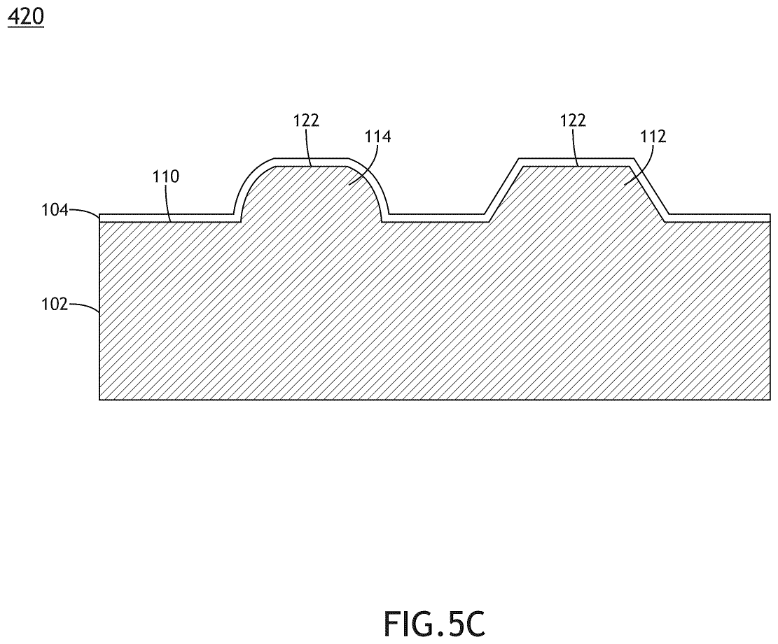

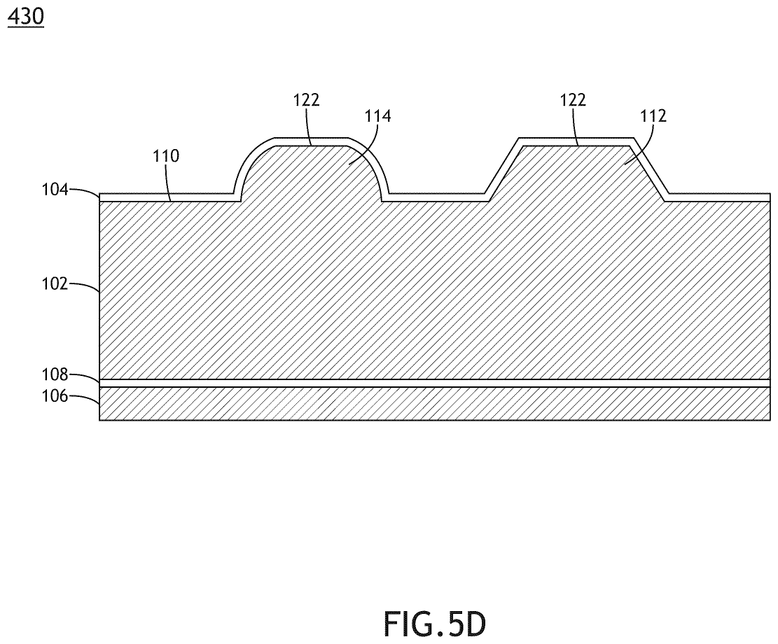

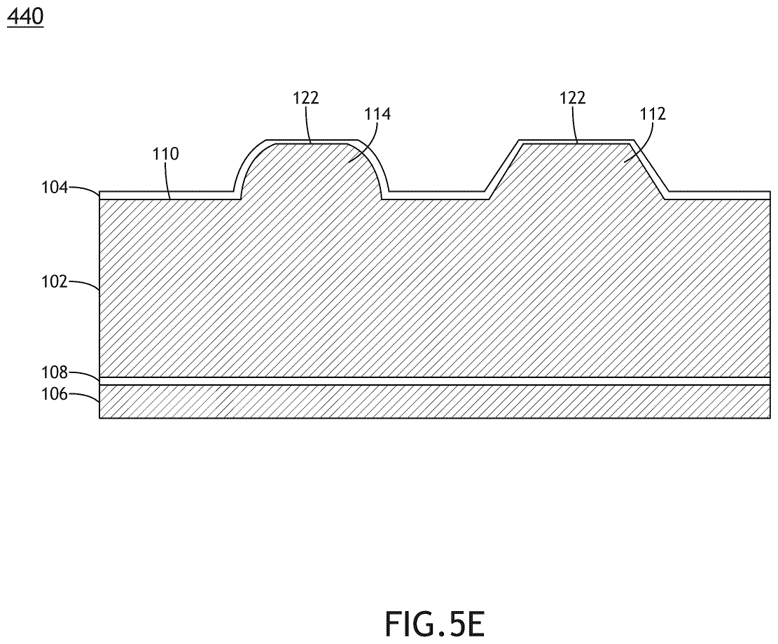

The method 400 may be further understood with reference to FIGS. 5A-5E. FIGS. 5A-5E illustrate the cross-section of FIG. 1B. FIG. 5A illustrates the sealing rings 112 and the rounded bumps 114 before polishing. FIG. 5B illustrates the sealing rings 112 and the rounded bumps 114 after polishing with the polished surface 122. FIG. 5C illustrates the carbon coating 104 coated on the chuck body 102. FIG. 5D illustrates the adhesive layer 108 adhering together the chuck body 102 and the bottom cover 106. FIG. 5E illustrates the portion of carbon coating 104 deposited on the polished surface 122 after being polished.

Referring generally again to the figures. Although much of the present disclosure is directed to the carbon coating 104 being a diamond-like carbon coating, this is not intended as a limitation of the present disclosure. The carbon coating 104 may be replaced by another coating, such as, but not limited to, an anodized coating or the like. The anodized coating may provide similar electrical resistance as the carbon coating 104.

It is further contemplated that each of the embodiments of the methods described above may include any other step(s) of any other method(s) described herein. In addition, each of the embodiments of the method described above may be performed by any of the systems described herein.

One skilled in the art will recognize that the herein described components operations, devices, objects, and the discussion accompanying them are used as examples for the sake of conceptual clarity and that various configuration modifications are contemplated. Consequently, as used herein, the specific exemplars set forth and the accompanying discussion are intended to be representative of their more general classes. In general, use of any specific exemplar is intended to be representative of its class, and the non-inclusion of specific components, operations, devices, and objects should not be taken as limiting.

As used herein, directional terms such as “top,” “bottom,” “over,” “under,” “upper,” “upward,” “lower,” “down,” and “downward” are intended to provide relative positions for purposes of description, and are not intended to designate an absolute frame of reference. Various modifications to the described embodiments will be apparent to those with skill in the art, and the general principles defined herein may be applied to other embodiments

With respect to the use of substantially any plural and/or singular terms herein, those having skill in the art can translate from the plural to the singular and/or from the singular to the plural as is appropriate to the context and/or application. The various singular/plural permutations are not expressly set forth herein for sake of clarity.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected,” or “coupled,” to each other to achieve the desired functionality, and any two components capable of being so associated can also be viewed as being “couplable,” to each other to achieve the desired functionality. Specific examples of couplable include but are not limited to physically mixable and/or physically interacting components and/or wirelessly interactable and/or wirelessly interacting components and/or logically interacting and/or logically interactable components.

Furthermore, it is to be understood that the invention is defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” and the like). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, and the like” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, and the like). In those instances where a convention analogous to “at least one of A, B, or C, and the like” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, and the like). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

It is believed that the present disclosure and many of its attendant advantages will be understood by the foregoing description, and it will be apparent that various changes may be made in the form, construction and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. A vacuum chuck comprising:
a chuck body, wherein the chuck body is formed from silicon carbide, wherein the chuck body comprises an unpolished surface, a plurality of sealing rings, a plurality of vacuum holes, and a polished surface, wherein the plurality of sealing rings axially extend from the unpolished surface, wherein the plurality of vacuum holes are defined by the unpolished surface, wherein the polished surface is a top surface of the chuck body, wherein the polished surface is defined by at least the plurality of sealing rings;
a bottom cover;
an adhesive layer, wherein the adhesive layer adheres together the chuck body and the bottom cover; and
a carbon coating, wherein the carbon coating is deposited on the polished surface, wherein the carbon coating has a thickness of equal to or less than ten micrometers.

2. The vacuum chuck of claim 1, wherein the carbon coating is a diamond-like carbon material.

3. The vacuum chuck of claim 2, wherein the diamond-like carbon material comprises an Sp2/Sp3 bond ratio of between 1.5 and 1.7.

4. The vacuum chuck of claim 1, wherein the unpolished surface, the plurality of sealing rings, the plurality of vacuum holes, and the polished surface are disposed on a top side of the chuck body.

5. The vacuum chuck of claim 1, wherein the plurality of sealing rings are concentric to a center axis of the chuck body.

6. The vacuum chuck of claim 5, wherein the plurality of vacuum holes are disposed radially within one or more of the plurality of sealing rings.

7. The vacuum chuck of claim 1, wherein a flatness of the polished surface is equal to or less than ten micrometers.

8. The vacuum chuck of claim 7, wherein the flatness is equal to or less than four micrometers.

9. The vacuum chuck of claim 1, wherein a surface roughness of the polished surface is equal to or less than 0.1 micrometer.

10. The vacuum chuck of claim 1, wherein a local slope of the polished surface is equal to or less than 100 arcseconds.

11. The vacuum chuck of claim 10, wherein the local slope is equal to or less than 25 arcseconds.

12. The vacuum chuck of claim 1, wherein the chuck body comprises a plurality of rounded bumps, wherein the plurality of rounded bumps axially extend from the unpolished surface, wherein the plurality of rounded bumps are distributed across the unpolished surface, wherein the polished surface is defined by at least the plurality of sealing rings and the plurality of rounded bumps.

13. The vacuum chuck of claim 1, wherein the chuck body comprises a plurality of pin seals, wherein the plurality of pin seals axially extend from the unpolished surface, wherein the polished surface is defined by at least the plurality of sealing rings and the plurality of pin seals, wherein the vacuum chuck comprises a plurality of lift pins, wherein the plurality of lift pins are disposed within and concentric to the plurality of pin seals, wherein the plurality of lift pins are configured to axially translate relative to the chuck body through the plurality of pin seals.

14. The vacuum chuck of claim 1, wherein the chuck body comprises a plurality of slots, wherein the plurality of slots are configured to receive an end effector.

15. The vacuum chuck of claim 1, wherein the chuck body comprises a plurality of standoffs, wherein the plurality of standoffs are disposed on a bottom side of the chuck body, wherein the plurality of standoffs axially extend through the bottom cover.

16. The vacuum chuck of claim 1, wherein the bottom cover comprises a plurality of vacuum pads, wherein the plurality of vacuum pads fluidically couple with the plurality of vacuum holes.

17. The vacuum chuck of claim 1, wherein the chuck body comprises a mixture of 20% silicon and 80% silicon carbide by weight.

18. The vacuum chuck of claim 1, wherein the carbon coating has a thickness of between 2 micrometers and 4 micrometers.

19. The vacuum chuck of claim 18, wherein the carbon coating has a surface resistance of greater than or equal to 10\hat{ }5 Ω/sq and less than 10\hat{ }11 Ω/sq.

20. An inspection system comprising:
a vacuum chuck comprising:
a chuck body, wherein the chuck body is formed from silicon carbide, wherein the chuck body comprises an unpolished surface, a plurality of sealing rings, a plurality of vacuum holes, and a polished surface, wherein the plurality of sealing rings axially extend from the unpolished surface, wherein the plurality of vacuum holes are defined by the unpolished surface, wherein the polished surface is a top surface of the chuck body, wherein the polished surface is defined by at least the plurality of sealing rings;
a bottom cover;
an adhesive layer, wherein the adhesive layer adheres together the chuck body and the bottom cover; and
a carbon coating, wherein the carbon coating is deposited on the polished surface, wherein the carbon coating has a thickness equal to or less than ten micrometers.

21. A method of manufacturing a vacuum chuck, the method comprising:
polishing a chuck body to form a polished surface, wherein the chuck body is formed from silicon carbide, wherein the chuck body comprises an unpolished surface, a plurality of sealing rings, a plurality of vacuum holes, and the polished surface, wherein the plurality of sealing rings axially extend from the unpolished surface, wherein the plurality of vacuum holes are defined by the unpolished surface, wherein the polished surface is a top surface of the chuck body, wherein the polished surface is defined by at least the plurality of sealing rings;
depositing a carbon coating on the chuck body, wherein the carbon coating is deposited on the polished surface, wherein the carbon coating has a thickness equal to or less than ten micrometers; and
adhering together the chuck body and a bottom cover by an adhesive layer after the carbon coating is deposited on the chuck body.

22. The method of claim 21, further comprising polishing the carbon coating deposited on the polished surface.
